(19) United States
(12) Patent Application Publication
(10) Pub. No.: US 2026/0082852 A1
(43) Pub. Date: Mar. 19, 2026

(54) MAPPING DEVICE AND LOAD PORT APPARATUS

(71) Applicant: TDK CORPORATION, Tokyo (JP)

(72) Inventors: Kodai SATO, Tokyo (JP); Tomoshi ABE, Tokyo (JP); Tatsuhiro KOTSUGAI, Tokyo (JP)

(73) Assignee: TDK CORPORATION, Tokyo (JP)

(21) Appl. No.: 19/327,486

(22) Filed: Sep. 12, 2025

(30) Foreign Application Priority Data
Sep. 13, 2024 (JP) 2024-159001

(51) Int. Cl. H10P 72/00; G01B 11/06

(52) U.S. Cl. CPC H10P 72/0604; G01B 11/06; H10P 72/0616; H10P 72/3411

(57) ABSTRACT

A mapping device capable of detecting a stored state of a square shaped plate-form object including: a first detection part having a first detection axis which crosses a first side and a second side perpendicular to the first side object to detect a first corner thickness; a second detection part having a second detection axis which crosses the first and third sides of the object to detect a second corner thickness; a first information acquiring unit acquiring a first information relating to a warpage amount in the first direction of the object; an adjustment calculation unit calculating an adjusted detection value relating to the thickness of the object in the first direction by adjusting, based on the first information, a sum of the first and second corner thicknesses or an average thereof; and a distinguishing unit distinguishing the stored state of the object using the adjusted detection value.

### TECHNICAL FIELD

The present disclosure relates to a mapping device and a load port apparatus.

### BACKGROUND

Devices such as load port apparatus for transporting a plate-form object such as a substrate are equipped with a mapping device which detects a stored state of the object stored in a container. The mapping device detects the number of objects and the positions of the objects stored in the container, and also detects whether the objects are properly stored (see Patent Document 1). The objects to be detected by the mapping device include a silicon substrate and the silicon substrate which has been treated, and also include a thin plate-form material such as a glass substrate.

On the other hand, as the object being transported in a semiconductor factory has become larger and thinner, the object which is stored in the container and transported have also become more diversified. For example, as similar to a silicon wafer, there is a demand to store a square shaped plate-form object larger than a silicon wafer in a sealed container for transporting in the factory. As a mapping device adapted for the square shaped plate-form object, a device which detects the corner of the square shaped object is proposed.

### PRIOR ART DOCUMENT

### Patent Document

[Patent Document 1] JP Patent No. 7443885

### SUMMARY

Regarding a mapping device, the present inventors have found that even in the case of a detected value obtained by a detection part which detects a corner of a square shaped object, the effect due to warpage of the object is non-negligible in regards with the detected value in a thickness direction. Although, the effect is smaller compared to a conventional device, the warpage of the object has influence on the detection part detecting the corner of the square shaped object regarding the detected value along a thickness direction (the first direction). Thus, in order to more accurately distinguish the stored state of the object(s) (such as one object is stored, or two objects are stacked and stored), there is a demand to reduce or remove the influence of the warpage of object from the detected value.

The present disclosure relates to a mapping device capable of detecting the stored state of the square shaped plate-form object more accurately.

In order to achieve the above-mentioned object, a mapping device of the present disclosure capable of detecting a stored state of a square shaped plate-form object including a plurality of square shaped plate-form objects stored in a container capable of storing the square shaped plate-form objects along a first direction while taking a space between each of the square shaped plate-form objects, includes: a first detection part having a first detection axis which crosses a first side and a second side being approximately perpendicular to the first side of the square shaped plate-form object to detect a first corner thickness corresponding to a length along the first direction that the first detection axis is blocked by the square shaped plate-form object when the first detection axis moves along the first direction; a second detection part having a second detection axis which crosses the first side of the square shaped plate-form object and a third side positioned at an opposite side of the second side being approximately perpendicular to the first side to detect a second corner thickness corresponding to a length along the first direction that the second detection axis is blocked by the square shaped plate-form object when the second detection axis moves along the first direction; a first information acquiring unit acquiring a first information relating to a warpage amount in the first direction of the square shaped plate-form object; an adjustment calculation unit calculating an adjusted detection value relating to the thickness of the square shaped plate-form object in the first direction by adjusting, based on the first information, a sum of the first corner thickness and the second corner thickness of the square shaped plate-form object or an average of the first corner thickness and the second corner thickness; and a distinguishing unit distinguishing the stored state of the square shaped plate-form object using the adjusted detection value.

The mapping device according to the present disclosure detects the first corner thickness and the second corner thickness using the first detection part and the second detection part; and the adjustment calculation unit adjusts, based on the information regarding the warpage amount of the square shaped object, the sum or the average of the first corner thickness and the second corner thickness. Examples of the first information which is information concerning the warpage amount of the square shaped object include information detected by other detection parts included in the same mapping device, information passed from other mapping devices and control devices to the target mapping device, and information calculated from these information. However, it is not particularly limited to these.

Such mapping device detects the first corner thickness and the second corner thickness where the influence of the warpage of the object is relatively small, and the sum or the average of the first corner thickness and the second corner thickness is adjusted based on the first information relating to the warpage amount. Hence, the stored state of the square shaped plate-form object can be detected more accurately. Particularly, by distinguishing the stored state of the square shaped plate-form object(s) using the adjusted detection value calculated in the mapping device, the stored state of the square shaped plate-form object(s), such as whether one object is stored or two objects are stacked and stored, can be accurately distinguished.

For example, the mapping device may include a third detection part having a third detection axis being longer than the first side and being approximately parallel to the first side of the square shaped plate-form object to detect a warpage index value corresponding to a length along the first direction that the third detection axis is blocked by the square shaped plate-form object when the third detection axis moves along the first direction; and wherein, the first information acquired by the first information acquiring unit is a detection result of the warpage index value obtained by the third detection part.

The third detection part carries out detection using the third detection axis which is relatively long and parallel to the first side; thus, the detected value of the third detection part is heavily influenced by the warpage amount of the square shaped plate-form object compared to the detected values of the first detection part and the second detection part. By carrying out adjustment based on the warpage index value which is heavily influenced by the warpage amount, in such mapping device, the influence of the warpage amount on the detected value is effectively reduced or removed; thus, the stored state of the square shaped plate-form object can be detected appropriately.

For example, the adjustment calculation unit may calculate a difference between a standard value and the warpage index value of the square shaped plate-form object, and an adjustment amount or an adjustment coefficient proportional to the difference between the standard value and the warpage index value may be applied to a sum of the first corner thickness and the second corner thickness or to an average of the first corner thickness and the second corner thickness to calculate the adjusted detection value.

A method of calculating the adjustment amount using the adjustment calculation unit is not particularly limited, and by using the adjustment amount or the adjustment coefficient proportional to the difference between the warpage index value and the standard value, an accurate adjusted value can be calculated with less calculation amount.

For example, the first detection part may include a first light emitting part and a first light receiving part; the second detection part may include a second light emitting part and a second light receiving part; and the first detection axis connects the first light emitting part and the first light receiving part, and the second detection axis may connect the second light emitting part and the second light receiving part.

Examples of the first detection part and the second detection part include an optical sensor, a magnetic sensor, a capacitance sensor, and an ultrasound sensor; and by using the optical sensor including a light emitting part and a light receiving part, the blocked length in the first direction of the square shaped object can be measured with high accuracy.

For example, the mapping device may include: a mapping arm including a width direction portion extending approximately parallel to the first side of the square shaped plate-form object, a first projection portion projecting approximately parallel to the second side from one side of the width direction portion, and a second projection portion projecting approximately parallel to the third side from the other side of the width direction portion; wherein one of the first light emitting part or the first light receiving part and one of the second light emitting part or the second light receiving part are provided to the width direction portion, the other one of the first emitting part or the first light receiving part is provided to the first projection portion, and the other one of the second light emitting part or the second light receiving part is provided to the second projection portion.

By using such mapping arm, the blocked length in the first direction of the square shaped object can be measured accurately and promptly using the first detection part and the second detection part.

For example, the first detection part may include a first light emitting part and a first light receiving part; the second detection part may include a second light emitting part and a second light receiving part; the third detection part may include a third light emitting part and a third light receiving part; and the mapping device may include a mapping arm including a width direction portion extending approximately parallel to the first side of the square shaped plate-form object, a first projection portion projecting approximately parallel to the second side from one side of the width direction portion, and a second projection portion projecting approximately parallel to the third side from the other side of the width direction portion; wherein one of the first light emitting part or the first light receiving part and one of the second light emitting part or the second light receiving part are provided to the width direction portion, the other one of the first emitting part or the first light receiving part and one of the third light emitting part or the third light receiving part are provided to the first projection portion, and the other one of the second light emitting part or the second light receiving part and the other one of the third light emitting part or the third light receiving part are provided to the second projection portion.

For example, by using such mapping arm, the blocked length in the first direction of the square shaped object can be detected accurately and promptly using the first detection part and the second detection part, and also the third detection part acquires the warpage index value as the first information regarding each polygon shaped object. Therefore, the mapping device including such mapping arm can promptly distinguish the stored state of the square shaped plate-form object.

For example, the mapping device may include a driving unit for moving the mapping arm along the first direction, and the first detection axis and the second detection axis sequentially cross the plurality of square shaped plate-form objects stored in the container to detect the first corner thickness and the second corner thickness of each of the square shaped plate-form objects.

By having such driving unit, the mapping device can accurately detect the stored state of the square shaped plate-form object in the container.

For example, a load port apparatus may include: any one of the mapping device mentioned in above, a mounting part for mounting a container, and a door to open and close a lid of the container.

The mapping device according to the present disclosure may be used in any devices, and for example, it may be suitably used as a part of an interface unit, such as a load port apparatus equipped to a semiconductor processing device, which passes and receives a substrate and the like using a container in the semiconductor factory.

### BRIEF DESCRIPTION DRAWINGS

FIG. 1 is a schematic diagram of a load port apparatus including a mapping device according to an embodiment of the present disclosure.

FIG. 2 is an explanatory diagram (partial cross section) showing a first step of a detection operation using the mapping device shown in FIG. 1.

FIG. 3 is an explanatory diagram (partial cross section) showing a second step of the detection operation using the mapping device shown in FIG. 1.

FIG. 4 is an explanatory diagram (partial cross section) showing a third step of the detection operation using the mapping device shown in FIG. 1.

FIG. 5 is a conceptual diagram showing a state inside the container during the detection operation using the mapping device shown in FIG. 1.

FIG. 6 is a plan diagram showing the arrangement relation between the mapping arm, the square shaped plate-form object, and the first to third detection parts which are provided to the mapping arm.

FIG. 7 is a partial enlarged view near a first projection portion of the mapping arm shown in FIG. 6.

FIG. 8 is a partial enlarged view near a first projection portion of the mapping arm according to a modified example.

FIG. 9 is a conceptual diagram showing properties of each of detected values acquired by the first to third detection parts shown in FIG. 8 and so on.

FIG. 10 is a flow chart showing a method for detecting the arrangement state of the mapping device shown in FIG. 1.

FIG. 11A and FIG. 11B are graphs showing an example of data which has been detected and calculated using the method of detection shown in FIG. 10.

### DETAILED DESCRIPTION

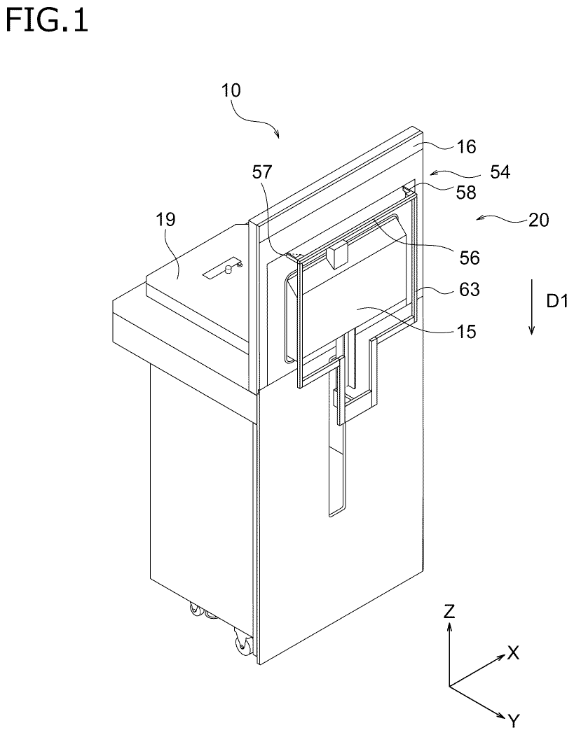

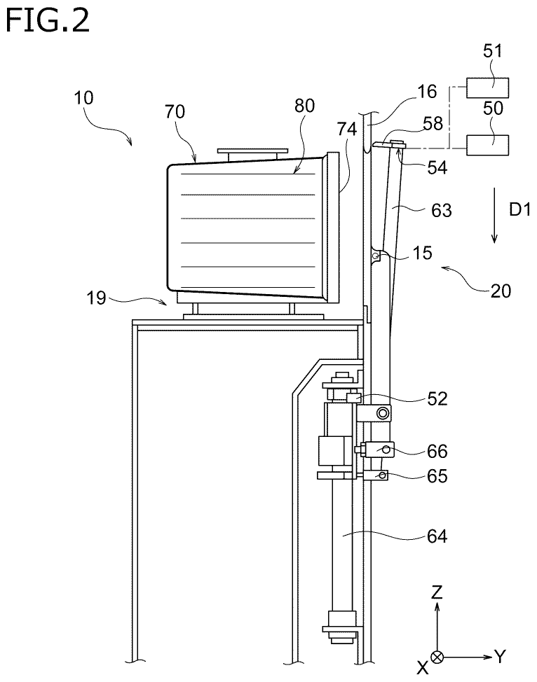

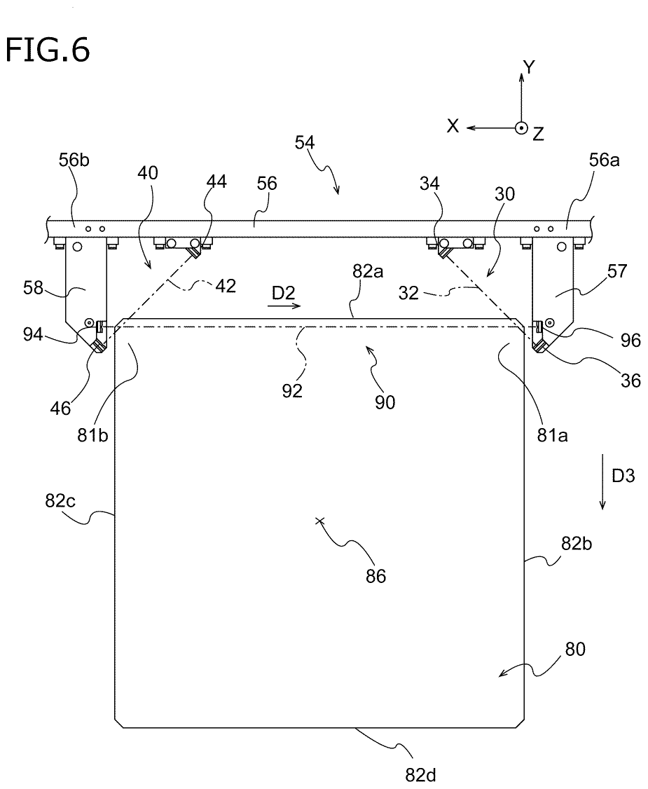

Below describes the present disclosure based on the embodiments shown in the figures. FIG. 1 is a schematic perspective diagram of a load port apparatus 10 including the mapping device 20 according to an embodiment of the present disclosure. The mapping device 20 according to the present embodiment is provided near a door 15 of the load port apparatus 10. The mapping device 20 detects a stored state of a substrate 80 (see FIG. 2 and FIG. 6) as a square shaped plate-form object in a container 70 (see FIG. 2) mounted on the load port apparatus 10.

The load port apparatus 10 is used by being installed to EFEM (not shown in the figure) in a semiconductor factory. The load port apparatus 10 functions as an interface unit for passing and receiving the substrate 80, which is being transported in the semiconductor factory while stored in the container 70 (see FIG. 2), from the container 70 to the predetermined semiconductor processing device. Note that, examples of the container 70 storing the substrate 80 includes FOUP, FOSB, and SMIF.

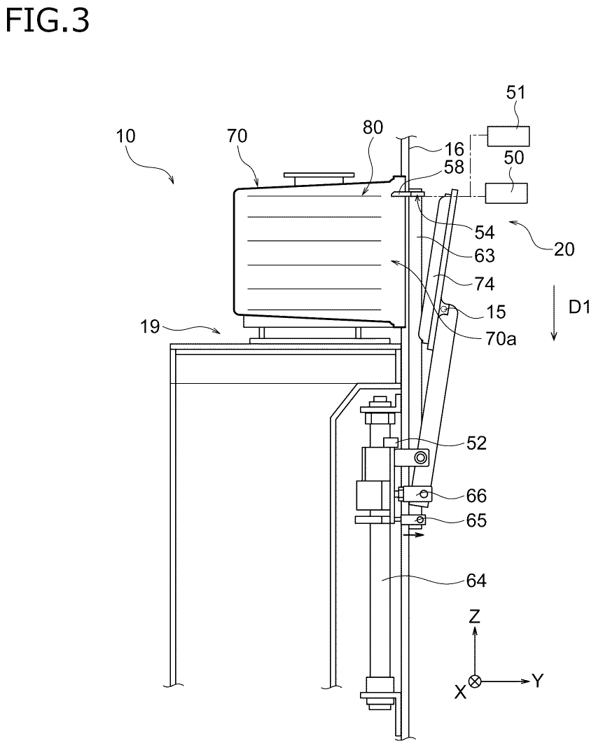

As shown in FIG. 2, the container 70 can store a plurality of substrates 80 along a first direction D1 while taking a space between the substrates. As shown in FIG. 2, the first direction D1 of the container 70 (the downward direction of the container 70) is parallel to a Z-axis direction (vertical direction) when the container 70 is mounted on the load port apparatus 10. The container 70 shown in FIG. 2 has a main opening 70a (see FIG. 3) for taking out the substrate 80 to a lateral side of the container 70 (FOUP type). Note that, there is no particular limitation of a method for opening and closing the container where the substrate 80 as the square shaped plate-form object which is a detection target of the mapping device 20 is stored; and it may be an opening and closing method which is different from that used for the container 70 such as SMIF type shown in FIG. 2.

As shown in FIG. 1, in addition to the mapping device 20, the load port apparatus 10 includes a mounting part 19 for mounting the container 70 storing the substrate 80, a frame 16 installed to close the opening of EFEM, and a door 15 which opens and closes the lid 74 of the container 70 and the frame opening of the frame 16. Note that, the mapping device 20 is not limited to those equipped to the load port apparatus 10 as shown in FIG. 1 and FIG. 2; and examples of the mapping device 20 include those detecting a stored state of the substrate 80 stored in the container 70 which is mounted on a device other than the load port apparatus 10 such as a storing slot of the container 70.

The mapping device 20 shown in FIG. 1 and FIG. 2 detects a stored state of the substrate 80 in the container 70. In addition to a mapping arm 54, the first detection part 30, the second detection part 40, and the third detection part 90 which are described later using FIG. 6 etc., the mapping arm 20 has a supporting structure which supports the mapping arm 54 such as a support arm 63 supporting the mapping arm 54. Also, the mapping arm 20 includes a driving unit which moves the mapping arm 54 and the support arm 63. As shown in FIG. 2, etc., the driving unit of the mapping device 20 includes a first moving means 64 allowing the mapping arm 54 and so on to move along the first direction D1, and a second moving means 65 allowing the mapping arm 54 and so on to move along the Y-axis direction.

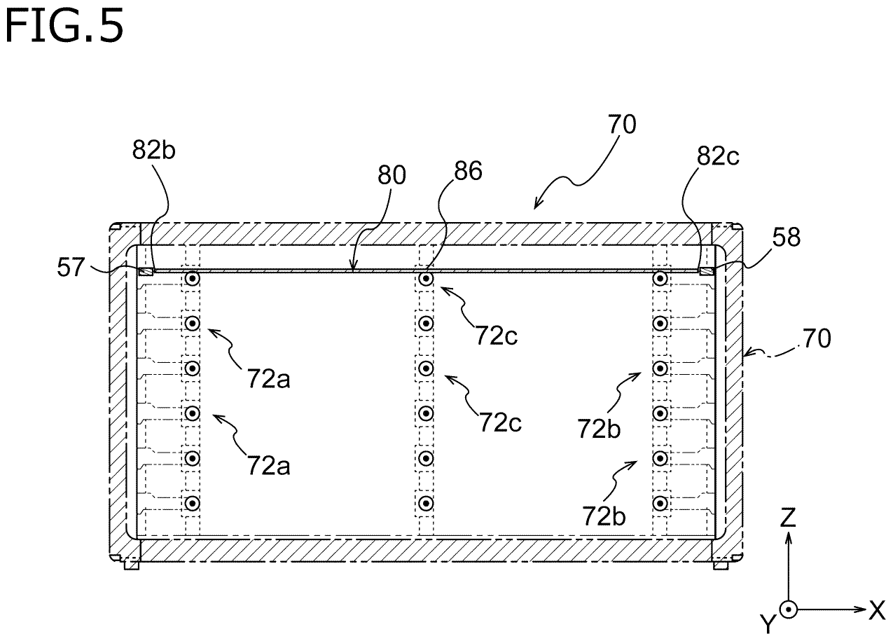

FIG. 5 is a cross-sectional view of the substrate 80 stored in the container 70; and the container 70 is viewed from the side of the door 15 (from the Y-axis positive direction side). Also, FIG. 6 is an enlarged diagram of a main part showing a part of the mapping device 20 shown in FIG. 1, and the substrate 80 which is a detection target of the first detection part 30, the second detection part 40, and the third detection part 90 included in the mapping device 20. Note that, in the description of the load port apparatus 10 and the mapping device 20, the vertical direction is the Z-axis direction, Y-axis direction is the direction which is perpendicular to the Z-axis and the mounting part 19 moving closer to and away from the frame 16, and the direction perpendicular to the Z-axis and the Y-axis is the X-axis.

As shown in FIG. 2 and FIG. 5, in the container 70, the plurality of substrates 80 is stored while taking a predetermined distance between each other along the first direction D1. As shown in FIG. 6, the substrate 80 is a flat plate-form which is roughly a rectangular shape when viewed from the Z-axis direction, and the substrate 80 are stored in the container 70 such that the two largest surfaces are extending approximately parallel to a horizontal direction. Note that, the container 70 may be capable of storing an object which is not a square shaped plate-from object such as a silicon wafer of a circular flat plate-form.

As shown in FIG. 6, when the substrate 80 is viewed from the Z-axis direction, the substrate 80 has a first side 82a which is closer to the main opening 70a of the container 70 than other sides and extending approximately parallel to an opening surface. Also, the substrate 80 which is roughly a rectangular shape includes a second side 82b being approximately perpendicular to the first side 82a, a third side 82c being approximately perpendicular to the first side 82a and positioned at the opposite side of the second side 82b, and a fourth side 82d being approximately parallel to the first side 82a and positioned at the opposite side of the first side 82a.

Also, the substrate 80 which is approximately rectangular shaped when viewed from the Z-axis direction has four corners. Among the four corners of the substrate 80, a first corner 81a shown in FIG. 6 is a corner which is between the first side 82a and the second side 82b, and a second corner 81b is a corner which is between the first side 82a and the third side 82c. Among the four corners of the substrate 80, the first corner 81a and the second corner 81b are positioned closer to the opening 70a than a center 86 of the substrate 80.

As shown in FIG. 5, the container 70 includes a first support member 72a, a second support member 72b, and a third support member 72c which support the substrate 80 as the square shaped plate-form object. The first to third support members 72a, 72b, and 72c extend along the Y-axis direction which is perpendicular to the opening 70a of the container 70 to support the substrate 80 from below.

The first support member 72a and the second support member 72b are arranged near the two side walls, among the side walls of the container 70, parallel to the YZ plane perpendicular to the opening 70a. As shown in FIG. 5, the first support member 72a supports the substrate 80 from below, particularly in the area of the substrate which is closer to second side 82b than to the center 86 and is positioned within a predetermined width from the second side 82b. Also, the second support member 72b supports the substrate 80 from below, particularly in the area of the substrate 80 which is closer to the third side 82c than to the center 86 and is positioned within a predetermined width from the third side 82c.

As shown by the two-dot dash line in FIG. 5, the first support member 72a and the second support member 72b are supported by arms extending from the side walls parallel to the YZ-plane of the container 70.

When the substrate 80 is viewed from the Z-axis direction which is the first direction D1, the third support member 72c is arranged so as to overlap with the center 86 of the substrate 80. The third support member 72c is arranged between the first support member 72a and the second support member 72b, and the third support member 72c can support the center area in the X-axis direction of the substrate 80 from below. The third support member 72c is fixed to the side wall which is opposite side from the opening 70a in the container 70.

The first to third support members 72a to 72c do not cross with the first side 82a when the substrate 80 in the container 70 is viewed from the Z-axis direction along the first direction D1, and the tips in the Y-axis positive direction are positioned closer to the center 86 than to the first side 82a (see FIG. 6). Therefore, when the substrate 80 in the container is viewed from the Z-axis direction, that is, from the first direction D1, the first to third support members 72a to 72c do not cross with the detection axes 32, 42, and 92 of the first to third detection parts 30, 40, and 90 which are described later. Thus, the first to third support members 72a to 72c are configured not to interfere with the detection of the substrate 80 carried out by the first to third detection parts 30, 40, and 90.

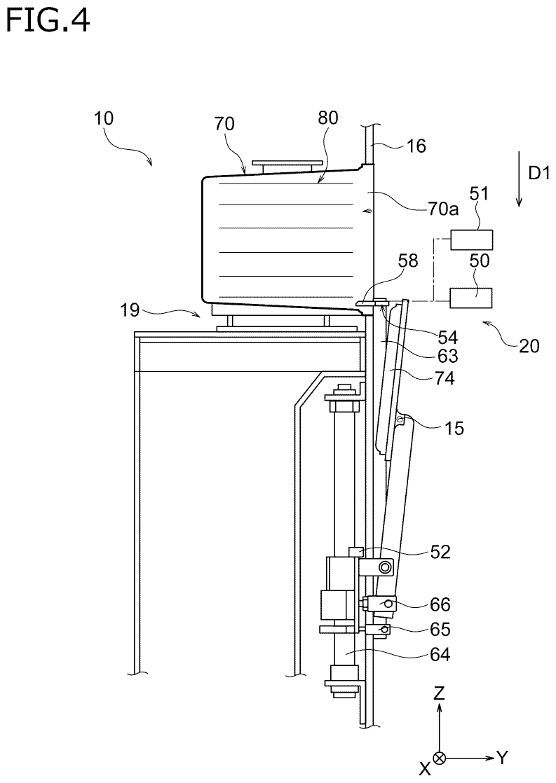

As it can be understood from FIG. 3 and FIG. 4 showing one example of the movement of the mapping process performed by the load port apparatus 10, part of the mapping device 20 is inserted in the container 70 from the opening 70a. As shown in FIG. 3 and FIG. 4, in the mapping device 20, at least part of the mapping arm 54, where the first detection part 30, the second detection part 40, and the third detection part 90 are installed, is configured so that it can be inserted in the container 70.

FIG. 6 is a plan view showing the mapping arm 54 of the mapping device 20 shown in FIG. 5, the first detection part 30, the second detection part 40, the third detection part 90, and the substrate 80 of the mapping device 20. As shown in FIG. 6, the mapping arm 54 has a width direction portion 56 extending approximately parallel to the first side 82a of the square shaped plate-form object, a first projection portion 57 projecting from one side 56a of the width direction portion 56 and extending approximately parallel to the second side 82b, and a second projection portion 58 projecting from the other side 56b of the width direction portion 56 and extending approximately parallel to the third side 82c. In the mapping arm 54, the first projection portion 57 is provided at the end part of the side 56a (the X-axis negative direction side) of the width direction portion 56 extending along the X-axis, and the second projection portion 58 is provided at the end part of the other side 56b (the X-axis positive direction side). The mapping arm 54 is installed approximately horizontally at the upper part of the support arm 63 shown in FIG. 1; and, the mapping arm 54 and the first detection part 30, the second detection part 40, and the third detection part 90 provided to the mapping arm 54 also move together with the movement of the support arm 63.

As shown in FIG. 5 and FIG. 6, when the substrate 80 is detected using the mapping device 20, the width direction portion 56 of the mapping arm 54 are arranged to be parallel with the opening 70a of the container 70. Also, the first projection portion 57 and the second projection portion 58 of the mapping arm 54 are arranged at the positions where the substrate 80 is placed between these along the X-axis.

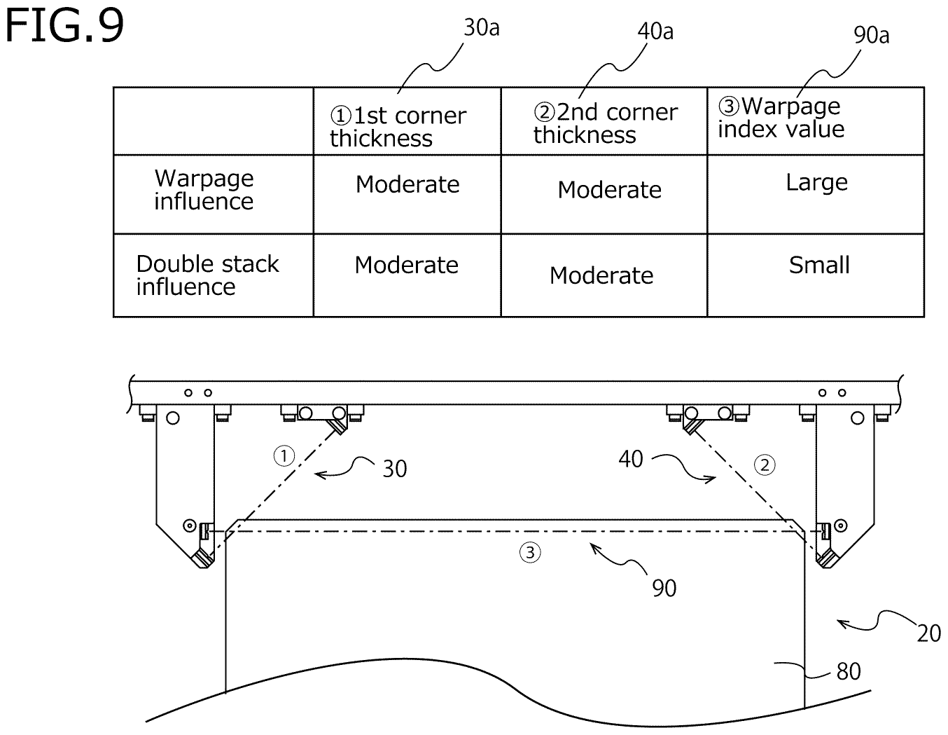

As shown in FIG. 6, the mapping device 20 includes the first detection part 30, the second detection part 40, and the third detection part 90; and each of the detection parts 30, 40, and 90 detects the substrate 80 in the container 70. The first detection part 30 has the first detection axis 32 which crosses the first side 82a and the second side 82b of the substrate 80 when the mapping arm 54 moves inside the container 70 in the first direction D1. The first detection part 30 detects a first corner thickness 30a which is a length along the first direction D1 (see FIG. 9) that the first detection axis 32 is blocked by the substrate 80 (particularly by the first corner 81a) when the first detection axis 32 moves in the first direction D1 along with the movement of the mapping arm 54.

More specifically, as shown in FIG. 6, the first detection part 30 is an optical sensor having a first light emitting part 34 and a first light receiving part 36. The first detection part 30 detects the first corner thickness 30a using a change in a light amount of the first light emitting part 34 which enters in the first light receiving part 36. The first detection axis 32 of the first detection part 30 connects the first light emitting part 34 and the first light receiving part 36. One of the first light emitting part 34 or the first light receiving part 36 is provided on the width direction portion 56 of the mapping arm 54, and the other one of the first light emitting part 34 or the first light receiving part 36 is provided on the first projection portion 57. In the mapping device 20, the first light emitting part 34 is provided on the width direction portion 56, and the first light receiving part 36 is provided on the first projection portion 57; however, the arrangement of the first light emitting part 34 and the first light receiving part 36 may be switched between each other.

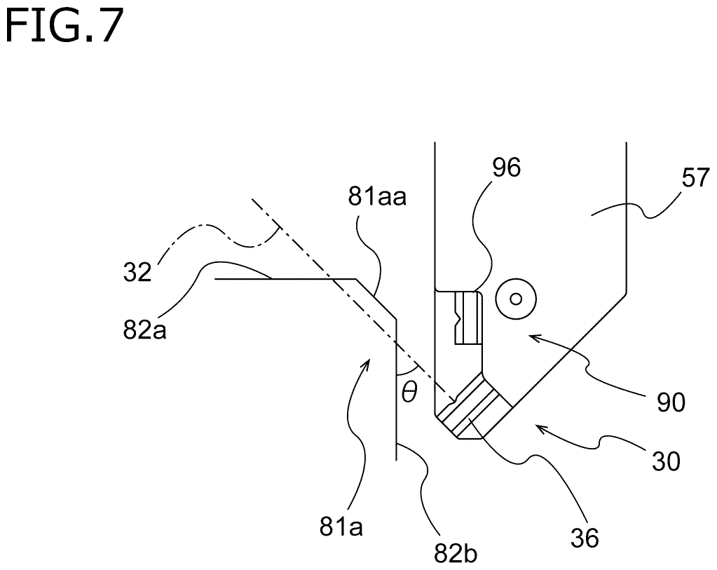

FIG. 7 is a partial enlarged diagram which the area near the tip of the first projection portion 57 of the mapping arm 54 is enlarged. As shown in FIG. 7, the angle θ between the first detection axis 32 and the second side 82b may, for example, be between 40 to 50 degrees. By setting the angle θ to 40 degrees or greater, the first detection axis 32 can avoid crossing a notch 81aa of the first corner 81a, and thereby, it is possible to suppress the fluctuation of the measurement values. Also, by setting the angle θ to less than 50 degrees, the warpage influence component included in the detected value of the first corner thickness 30a can be suppressed.

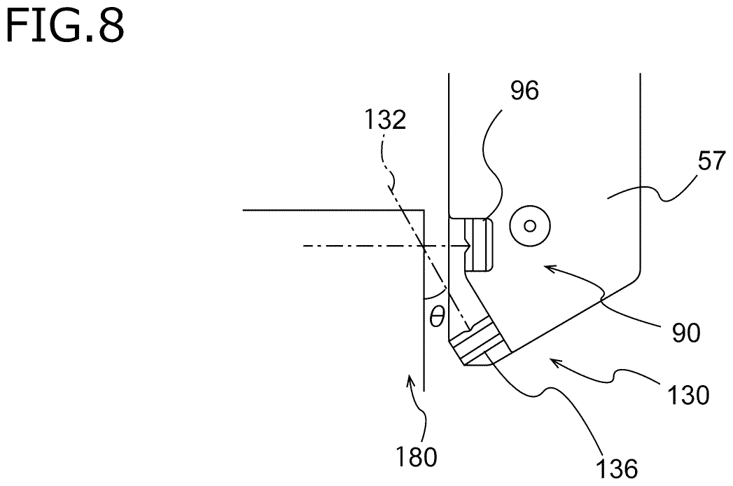

FIG. 8 is a schematic diagram showing a first light receiving part 136 and a first detection axis 132 of a first detection part 130 of a mapping device 180 according to a modified example. As shown in FIG. 8, in the case that the substrate 80 does not include a notch 81aa, an angle θ between the first detection axis 132 and the second side 82b may, for example, be between 20 degrees or greater and less than 40 degrees. The same applies to the angle between the second detection axis 42 and the third side 82c of the second detection part 40 which is described later.

The second detection part 40 includes the second detection axis 42 which crosses the first side 82a and the third side 82c of the substrate 80 when the mapping arm 54 moves inside the container 70 in the first direction D1. The second detection part 40 detects a second corner thickness 40a which is a length along the first direction D1 (see FIG. 9) that the second detection axis 42 is blocked by the substrate 80 (particularly by the second corner 81b) when the second detection axis 42 moves in the first direction D1 together with the movement of the mapping arm 54.

More specifically, as shown in FIG. 6, the second detection part 40 is an optical sensor having a second light emitting part 44 and a second light receiving part 46. The second detection part 40 detects the second corner thickness 40a using a change in a light amount of the second light emitting part 44 which enters the second light receiving part 46. The second detection axis 42 of the second detection part 40 connects the second light emitting part 44 and the second light receiving part 46. One of the second light emitting part 44 or the second light receiving part 46 is provided on the width direction portion 56 of the mapping arm 54, and the other one of the second light emitting part 44 or the second light receiving part 46 is provided on the second projection portion 58. In the mapping device 20, the second light emitting part 44 is provided on the width direction portion 56, and the second light receiving part 46 is provided on the second projection portion 58; however, the arrangement of the second light emitting part 44 and the second light receiving part 46 may be switched between each other.

In regards with the second detection part 40, as similar to the case of the first detection axis 32 of the first detection part 30 shown in FIG. 7, the angle between the second detection axis 42 and the third side 82c may be between 40 to 50 degrees. Note that, as shown in FIG. 6, the first detection part 30 and the second detection part 40 are arranged to be mirror image symmetrical across a line passing through the center 86 of the substrate 80 and parallel to the second side 82b and the third side 82c. Note that, the configurations of the first detection part 30 and the second detection part 40 are not limited to the example shown in FIG. 6, and the first detection part 30 and the second detection part 40 may be arranged asymmetrically.

The third detection part 90 has a third detection axis 92 which is approximately parallel to the first side 82a of the substrate 80 and is longer than the first side 82a. The third detection part 90 includes the second detection axis 42 which crosses the second side 82b and the third side 82c of the substrate 80 when the mapping arm 54 moves inside the container 70 in the first direction D1. The third detection part 90 detects the warpage index value 90a (see FIG. 9) which is a length along the first direction D1 that the third detection axis 92 is blocked by the substrate 80 (particularly, an area near the first side 82a including the entire first side 82a of the substrate 80) when the third detection axis 92 moves in the first direction D1 together with the movement of the mapping arm 54.

More specifically, as shown in FIG. 6, the third detection part 90 is an optical sensor having a third light emitting part 94 and a third light receiving part 96. The third detection part 90 detects the warpage index value 90a using a change in a light amount of the third light emitting part 94 which enters the third light receiving part 96. The third detection axis 92 of the third detection part 90 connects the third light emitting part 94 and the third light receiving part 96. One of the third light emitting part 94 or the third light receiving part 96 is provided on the first projection portion 57 of the mapping arm 54, and the other one of the third light emitting part 94 or the third light receiving part 96 is provided on the second projection portion 58. In the mapping device 20, the third light emitting part 94 is provided on the first projection portion 57, and the third light receiving part 96 is provided on the second projection portion 58; however, the arrangement of the third light emitting part 94 and the third light receiving part 96 may be switched between each other.

As mentioned in above, the first detection part 30, the second detection part 40, and the third detection part 90 included in the mapping device 20 are optical sensors (photoelectric sensor); however, the first detection part 30, the second detection part 40, and the third detection part 90 are not limited to optical sensors. For example, other transmission-type sensors such as an ultrasonic wave sensor and a magnetic sensor may be used as the mapping device 20.

Also, examples of the first light emitting part 34, the second light emitting part 44, and the third light emitting part 94 included in the mapping device 20 include visible light LED, infrared LED, ultraviolet ray LED; however, it is not limited to these, and the light emitting part other than LED such as LD (laser diode) may be used. Also, examples of the first light receiving part 36, the second light receiving part 46, and the third light receiving part 96 included in the mapping device 20 include a phototransistor, a photodiode, and an infrared detector; however, the light receiving parts are not limited to these.

As shown in FIG. 2 which is a schematic diagram of the load port apparatus 10, the mapping device 20 has a first moving means 64 and a second moving means 65 which are a driving unit for moving the mapping arm 54 and for moving the first to third detection parts 30, 40, and 90. As it can be understood by comparing FIG. 3 and FIG. 4, the first moving means 64 moves the mapping arm 54 along the Z-axis direction which is the first direction D1

Further, as it can be understood by comparing FIG. 2 and FIG. 3, the second moving means 65 shown in FIG. 2 moves the mapping arm 54 along the Y-axis direction which is the second direction. The second moving means 65 rotates the support arm 63, or moves the support arm 63 and the mapping arm 54 parallel along the Y-axis direction; thereby, the first to third detection parts 30, 40, and 90 move in the Y-axis direction. The third moving means 66 shown in FIG. 2 can move the door 15 separately from the mapping arm 54, the support arm 63, etc., and the third moving means 66 are used for opening and closing the lid 74 of the container 70.

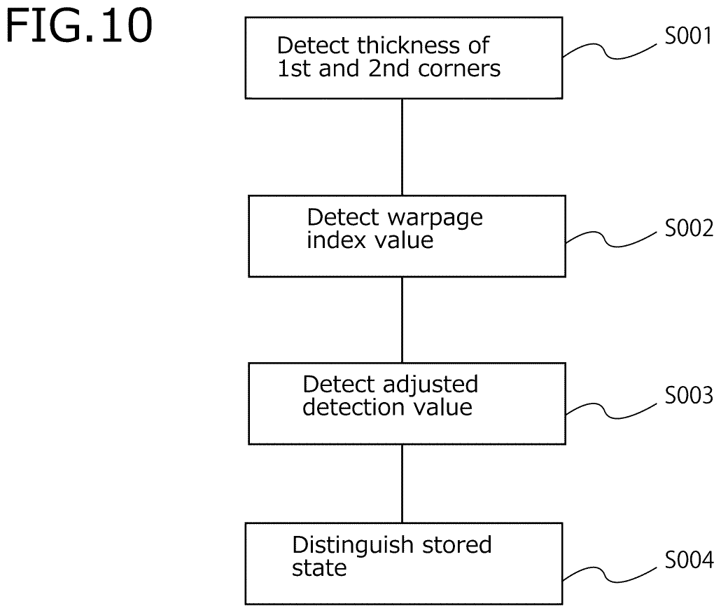

The operation of the load port apparatus 10 during the detection operation of the mapping device 20 is explained using FIG. 2 to FIG. 4, FIG. 10, etc. FIG. 2 shows the first step of detecting the substrate 80 using the mapping device 20. In the first step shown in FIG. 2, the container 70 storing the substrate 80 is mounted on the mounting part 19 of the load port apparatus 10, and the lid 74 of the container 70 is closed; hence, the container 70 is not connected to the frame 16 of the load port apparatus 10. Also, in the state shown in FIG. 2, the mapping device 20 itself has not started the detection operation.

FIG. 3 shows the second step of detecting the substrate 80 using the mapping device 20. In the second step shown in FIG. 3, the container 70 mounted on the mounting part 19 is connected to the frame 16, and the lid 74 of the container 70 is opened by the door 15. The door 15 engages with the lid 74 of the container 70 while engaging with the frame 16 shown in FIG. 2, and then, the third moving means 66 pulls the door 15 to the Y-axis positive direction as shown in FIG. 3. Thereby, the lid 74 of the container 70 is opened.

Further, the second moving means 65 of the mapping device 20 moves the support arm 63 and the mapping arm 54, and the first to third detection parts 30, 40, and 90 provided to the mapping arm 54 (see FIG. 6) are inserted in the container 70. Thereby, the first to third detection axes 32, 42, and 92 of the first to third detection parts 30, 40, and 90 are arranged to cross the substrate 80 when these are viewed from above as shown in FIG. 6.

Also, in the state shown in FIG. 3, the first to third detection axes 32, 42, and 92 of the first to third detection parts 30, 40, and 90 are arranged at the positions higher than the substrate 80 stored in the upper most slot of the container 70. Note that, during the operation of inserting the mapping arm 54 and the first to third detection parts 30, 40, and 90 in the container 70, the first moving means 64 may move the mapping arm 54 and the support arm 63 in the Z-axis direction to adjust the position in the Z-axis direction.

FIG. 4 shows the third step of the detection operation of the substrate 80 using the mapping device 20. In the third step shown in FIG. 4, the first moving means 64 as the driving unit moves the mapping arm 54 in the Z-axis direction; thereby, the first to third detection parts 30, 40, and 90 arranged at the positions higher than the substrate 80 stored in the upper most slot shown in FIG. 3 can move to the positions lower than the substrate 80 stored in the lowest slot as shown in FIG. 4.

That is, the first moving means 64 moves the mapping arm 54 along the first direction D1; thereby, the first detection axis 32, the second detection axis 42, and the third detection axis 92 sequentially cross with each of the plurality of substrates 80 stored in the container 70. Here, the first detection part 30, the second detection part 40, and the third detection part 90 output a detection signal, which changes by being blocked by the substrate 80, to a calculation unit including the adjustment calculation unit 50 and a distinguishing unit 51 of the mapping device 20 shown in FIG. 4. Also, the mapping device 20 has a sensor position detection part 52, and the sensor position detection part 52 detects the positions of the first to third detection parts 30, 40, and 90 in the Z-axis direction. The detection signal concerning the position are output to the calculation unit including the adjustment calculation unit 50 and the distinguishing unit 51.

FIG. 10 is a flow chart showing a sequence of process for distinguishing the stored state of the substrate 80 by the calculation unit etc. of the mapping device 20. In a step S001 shown in FIG. 10, the first detection part 30 and the second detection part 40 shown in FIG. 6 detect the first corner thickness 30a and the second corner thickness 40a relating to the plurality of substrates 80 stored in the container 70.

Also, in a step S002 shown in FIG. 10, the third detection part 90 shown in FIG. 6 detects the warpage index value 90a regarding the plurality of substrates 80 stored in the container 70. As discussed later, the detection using the third detection part 90 carried out in the step S002 corresponds to an acquisition operation of the first information which relates to the warpage amount in the first direction D1 of the substrate 80; and the third detection part 90 of the mapping device 20 functions as a first information acquisition unit which acquires the first information. Note that, the process done in the step S001 and the step S002 shown in FIG. 10 are those described as part of the operation of the third step of detection operation of the substrate 80 carried out by the above-mentioned mapping device 20.

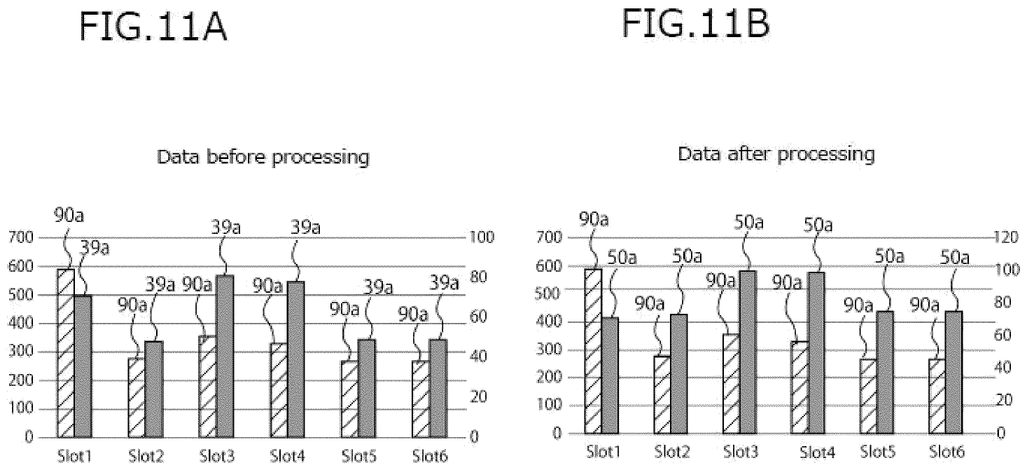

Next, in a step S003 shown in FIG. 10, using the detected values in the step S001 and S002, the adjustment calculation unit 50 of the mapping device 20 calculates the adjusted detection value 50a relating to the thickness of the substrate 80 in the first direction D1 (see FIG. 11). That is, in the step S003, the adjustment calculation unit 50 of the mapping device 20 carries out adjustment, which is based on the first information relating to the warpage amount of the substrate 80 in the first direction, to the sum or the average value 39a of the first corner thickness 30a and the second corner thickness 40a of the substrate 80 detected in the step S001 (see FIG. 11). Also, the adjustment calculation unit 50 uses the warpage index value 90a of the substrate 80 which is the detection result obtained by the third detection part 90 in the step S002 as the first information to be used in the step S003.

More specifically, the adjustment calculation unit 50 calculates the difference between the standard value and the warpage index value 90a of each substrate 80. The standard value used for calculating the difference is not particularly limited, and examples of the standard value include a maximum value, a median value, or a minimum value of the warpage index value 90a in the container 70. Next, the adjustment calculation unit 50 applies the adjustment amount or the adjustment coefficient which is proportional to the difference between the standard value and the warpage index value 90a (“warpage index value 90a”-“standard value”) to the sum or the average of the first corner thickness 30a and the second corner thickness 40a of the substrate 80 detected in the step S001. Thereby, the adjusted detection value 50a is calculated.

In the step S004 shown in FIG. 10, the distinguishing unit 51 of the mapping device 20 (see FIG. 2 to FIG. 3) distinguishes the stored state of the substrate 80 using the adjusted detection value calculated at the adjustment calculation unit 50 in the step S003 (see FIG. 11). More specifically, in the case that the adjusted detection value 50a is within a predetermined range, the distinguishing unit 51 determines that the substrate 80 is properly stored in the corresponding position (slot). Also, in the case that the adjusted detection value 50a is below the predetermined range, the distinguishing unit 51 determines that the substrate 80 is not stored in the corresponding position (slot) (empty slot). Also, in the case that the adjusted detection value 50a is above the predetermined range, the distinguishing unit 51 determines that the substrate 80 is stored in an improper state such as two substrates are stacked in the corresponding position (slot).

FIG. 9 is a conceptual diagram showing characteristics of the first corner thickness 30a detected by the first detection part 30 of the mapping device 20, the second corner thickness 40a detected by the second detection part 40 of the mapping device 20, and the warpage index value 90a detected by the third detection part 90 of the mapping device 20. As shown in FIG. 9, the warpage index value 90a detected by the third detection part 90 is greatly influenced by the warpage amount of the substrate 80 compared to the first corner thickness 30a and the second corner thickness 40a. Further, the warpage index value 90a is less influenced by the two stacked substrates 80 compared to the first corner thickness 30a and the second corner thickness 40a. Although the reason for this complex, the warpage of the substrate 80 more apparent as the height difference between the center part and the end part of the substrate 80 in the Y-axis direction. Thus, one possible reason for this is that the warpage is thought to impose great influence on the detection value detected by the third detection axis 92 which crosses the substrate 80 in the Y-axis direction.

The mapping device 20 detects the first corner thickness 30a and the second corner thickness 40a where the influence of the warpage of the substrate 80 are relatively small, and also the sum and the average of the first corner thickness 30a and the second thickness 40a are adjusted based on the warpage index value 90a which is the first information relating to the warpage amount. Thus, the stored state of the substrate 80 as the square shaped plate-form object, specifically whether the substrate is properly stored or improperly stored such as two substrates being stacked can be detected accurately.

FIGS. 11A and 11B are graphs showing a specific example of a stored state of the substrate 80 in the container 70 detected using the mapping device 20 which is the same one as the one shown in FIG. 1 to FIG. 7. FIG. 11A and FIG. 11B show the detection results of the slots (Slot 1 to Slot 6) of the container 70 detected using the mapping device 20. In regards with the slots (Slot 1 to Slot 6), FIG. 11A shows the warpage index value 90a (left) and the average 39a (right) of the first corner thickness 30a and the second corner thickness 40a. Note that, in Slot 1, Slot 2, Slot 5, and Slot 6, the substrates 80 are properly stored, and in Slot 3 and Slot 4, the substrates 80 are improperly stored as two substrates are being stacked.

As shown in FIG. 11A, in regards with the slots (Slot 1 to Slot 6), when the average 39a (right) of the first corner thickness 30a and the second corner thickness 40a are compared, Slot 1 indicating that the substrate is properly stored, is only slightly different from the values of Slot 3 and Slot 4 where the substrates are improperly stored. Therefore, by simply comparing the average 39a (right) of the first corner thickness 30a and the second corner thickness 40a, there may be cases which are difficult to accurately distinguish the properly stored state and the improperly stored state.

Note that regarding FIG. 11A, when the warpage index values 90a (left) of the slots (Slot 1 to Slot 6) are compared, Slot 1 is larger than other slots (Slot 2 to Slot 6). That is, in regards with Slot 1, the reason for the average 39a (right) of the first corner thickness 30a and the second corner thickness 40a being large is thought to be influenced by the substrate 80 of Slot 1 being warped largely.

Further, in FIG. 11B, the warpage index value 90a (left) and the adjusted detection value 50a of each slot (Slot 1 to Slot 6) are shown. When the adjusted detection values 50a are compared, the values are separated into two groups, which are properly stored Slot 1, Slot 2, Slot 5, and Slot 6, and improperly stored Slot 3 and Slot 4. Thus, by using the adjusted detection value 50a, the mapping device 20 can accurately distinguish the properly stored state and the improperly stored state (such as two substrates being stacked and stored) even in the case that the warpage amounts of the substrates 80 stored in the slots vary.

Herein above, the mapping device 20 and the load port apparatus according to the present disclosure were described using the embodiments and modified examples; however, the technical scope of the present disclosure is not limited to the above-mentioned embodiments and the modified examples, and it is obvious that various other embodiments are within the technical scope of the present disclosure. For example, the first information relating to the warpage amount that the first information acquisition unit of the mapping device 20 acquires is not limited to the warpage index value 90a that the third detection part 90 acquires. Other examples of the first information relating to the warpage amount include, a detection information acquired by the device which was performed to the target substrate 80 right before acquiring the information, a calculated information based on the shape, material, processing history, etc., of the substrate 80. Also, in the description of the operation of the mapping arm 54 using FIG. 3 to FIG. 5, the first direction D1 was defined as downward direction; however, the first direction D1 may be upward direction.

REFERENCE SIGNS LIST

| | |
|---|---|
| 10 | Load port apparatus |
| 15 | Door |
| 16 | Frame |
| 19 | Mounting part |
| 20 | Mapping |
| 64 | First moving means |
| 65 | Second moving means |
| 30 | First detection part |
| 32 | First detection axis |
| 34 | First light emitting part |
| 36 | First light receiving part |
| 39a | Average |
| 40 | Second detection part |
| 42 | Second detection axis |
| 44 | Second light emitting part |
| 46 | Second light receiving part |
| 90 | Third detection part |
| 92 | Third detection axis |
| 94 | Third light emitting part |
| 96 | Third light receiving part |
| 90a | Warpage index value |
| 50 | Adjustment calculation unit |
| 50a | Adjusted detection value |
| 51 | Distinguishing unit |
| 52 | Sensor position detection unit |
| 54 | Mapping arm |
| 56 | Width direction portion |
| 56a | One side |
| 56b | The other side |
| 57 | First projection portion |
| 58 | Second projection portion |
| 63 | Support arm |
| 66 | Third moving means |
| 70 | Container |
| 70a | Opening |
| 72a | First support member |
| 72b | Second support member |
| 72c | Third support member |
| 74 | Lid |
| 80 | Substrate |
| 81a | First corner |
| 81b | Second corner |
| 82a | First side |
| 82b | Second side |
| 82c | Third side |
| 82d | Fourth side |
| 86 | Center |

What is claimed is:

1. A mapping device capable of detecting a stored state of a square shaped plate-form object comprising a plurality of square shaped plate-form objects stored in a container capable of storing the square shaped plate-form objects along a first direction while taking a space between each of the square shaped plate-form objects, comprising:
a first detection part having a first detection axis which crosses a first side and a second side being approximately perpendicular to the first side of the square shaped plate-form object to detect a first corner thickness corresponding to a length along the first direction that the first detection axis is blocked by the square shaped plate-form object when the first detection axis moves along the first direction;
a second detection part having a second detection axis which crosses the first side of the square shaped plate-form object and a third side positioned at an opposite side of the second side being approximately perpendicular to the first side to detect a second corner thickness corresponding to a length along the first direction that the second detection axis is blocked by the square shaped plate-form object when the second detection axis moves along the first direction;
a first information acquiring unit acquiring a first information relating to a warpage amount in the first direction of the square shaped plate-form object;
an adjustment calculation unit calculating an adjusted detection value relating to the thickness of the square shaped plate-form object in the first direction by adjusting, based on the first information, a sum of the first corner thickness and the second corner thickness of the square shaped plate-form object or an average of the first corner thickness and the second corner thickness; and
a distinguishing unit distinguishing the stored state of the square shaped plate-form object using the adjusted detection value.

2. The mapping device according to claim 1 further comprising:
a third detection part having a third detection axis being longer than the first side and being approximately parallel to the first side of the square shaped plate-form object to detect a warpage index value corresponding to a length along the first direction that the third detection axis is blocked by the square shaped plate-form object when the third detection axis moves along the first direction; and
wherein, the first information acquired by the first information acquiring unit is a detection result of the warpage index value obtained by the third detection part.

3. The mapping device according to claim 2, wherein the adjustment calculation unit calculates a difference between a standard value and the warpage index value of the square shaped plate-form object, and an adjustment amount or an adjustment coefficient proportional to the difference between the standard value and the warpage index value is applied to a sum of the first corner thickness and the second corner thickness or to an average of the first corner thickness and the second corner thickness to calculate the adjusted detection value.

4. The mapping device according to claim 1, wherein
the first detection part comprises a first light emitting part and a first light receiving part;
the second detection part comprises a second light emitting part and a second light receiving part; and
the first detection axis connects the first light emitting part and the first light receiving part, and the second detection axis connects the second light emitting part and the second light receiving part.

5. The mapping device according to claim 4, comprising:
a mapping arm including
a width direction portion extending approximately parallel to the first side of the square shaped plate-form object,
a first projection portion projecting approximately parallel to the second side from one side of the width direction portion, and
a second projection portion projecting approximately parallel to the third side from the other side of the width direction portion;
wherein one of the first light emitting part or the first light receiving part and
one of the second light emitting part or the second light receiving part are provided to the width direction portion,
the other one of the first emitting part or the first light receiving part is provided to the first projection portion, and
the other one of the second light emitting part or the second light receiving part is provided to the second projection portion.

6. The mapping device according to claim 2, wherein
the first detection part comprises a first light emitting part and a first light receiving part;
the second detection part comprises a second light emitting part and a second light receiving part;
the third detection part comprises a third light emitting part and a third light receiving part; and
the mapping device comprises a mapping arm including
a width direction portion extending approximately parallel to the first side of the square shaped plate-form object,
a first projection portion projecting approximately parallel to the second side from one side of the width direction portion, and
a second projection portion projecting approximately parallel to the third side from the other side of the width direction portion;
wherein one of the first light emitting part or the first light receiving part and one of the second light emitting part or the second light receiving part are provided to the width direction portion,
the other one of the first emitting part or the first light receiving part and one of the third light emitting part or the third light receiving part are provided to the first projection portion, and
the other one of the second light emitting part or the second light receiving part and the other one of the third light emitting part or the third light receiving part are provided to the second projection portion.

7. The mapping device claim 5, comprising:
a driving unit for moving the mapping arm along the first direction, and the first detection axis and the second detection axis sequentially cross the plurality of square shaped plate-form objects stored in the container to detect the first corner thickness and the second corner thickness of each of the square shaped plate-form objects.

8. A load port apparatus comprising:
the mapping device according to claim 7,
a mounting part for mounting a container, and
a door to open and close a lid of the container.
